(19) United States
(12) Patent Application Publication
(10) Pub. No.: US 2026/0343895 A1
(43) Pub. Date: Oct. 29, 2026

(54) BITCELLS FOR A FERROELECTRIC RANDOM-ACCESS MEMORY DEVICE

(71) Applicant: GlobalFoundries Singapore Pte. Ltd., Singapore (SG)

(72) Inventors: Goh Kian Hui, Singapore (SG); Shyue Seng Tan, Singapore (SG); Khee Yong Lim, Singapore (SG); Kiok Boone Elgin Quek, Singapore (SG)

(21) Appl. No.: 19/188,107

(22) Filed: Apr. 24, 2025

(51) Int. Cl. H10B 53/30; H10B 51/10; H10B 51/30; H10B 53/10; H10D 1/00; H10D 1/68; H10D 30/01; H10D 30/69; H10D 64/01

(52) U.S. Cl. CPC H10B 53/30; H10B 51/10; H10B 51/30; H10B 53/10; H10D 1/043; H10D 1/716; H10D 30/0415; H10D 30/701; H10D 64/033

(57) ABSTRACT

Structures including a transistor and a ferroelectric capacitor, and methods of making such structures. The structure comprises a field-effect transistor including a source/drain region, and a capacitor including a first metal layer, a second metal layer, and a ferroelectric layer. The first metal layer includes a first vertically-extending section and a second vertically-extending section surrounding the first vertically-extending section. The second metal layer is arranged between the first vertically-extending section of the first metal layer and the second vertically-extending section of the first metal layer. The ferroelectric layer is arranged between the first metal layer and the second metal layer, and the second vertically-extending section of the first metal layer adjoins the source/drain region.

### BACKGROUND

This disclosure relates to integrated circuits and semiconductor device fabrication and, more specifically, to structures including a transistor and a ferroelectric capacitor, and methods of forming such structures.

A ferroelectric random-access memory device represents one category of embedded non-volatile memory technology. A bitcell of a ferroelectric random-access memory device typically includes a ferroelectric capacitor and an access transistor that controls operations used to write, erase, and read the ferroelectric capacitor. Because ferroelectric memory elements are non-volatile, bits of binary data are retained as stored content by the ferroelectric memory elements when the ferroelectric random-access memory device is unpowered. The non-volatility of a ferroelectric random-access memory device contrasts with volatile memory technologies, such as a static random-access memory device in which the stored content is eventually lost when unpowered and a dynamic random-access memory device in which the stored content is lost unless periodically refreshed.

Data is stored in a ferroelectric random-access memory device by applying an electric field to the ferroelectric capacitor, which changes the polarization of its constituent ferroelectric material. Stored data may be read from a ferroelectric random-access memory device without alteration by applying a small electric field to the ferroelectric material.

Improved structures including a transistor and a ferroelectric capacitor, and methods of forming such structures, are needed.

### SUMMARY

In an embodiment, a structure comprises a field-effect transistor including a source/drain region, and a capacitor including a first metal layer, a second metal layer, and a ferroelectric layer. The first metal layer includes a first vertically-extending section and a second vertically-extending section surrounding the first vertically-extending section. The second metal layer is arranged between the first vertically-extending section of the first metal layer and the second vertically-extending section of the first metal layer. The ferroelectric layer is arranged between the first metal layer and the second metal layer, and the second vertically-extending section of the first metal layer adjoins the source/drain region.

A structure comprises a field-effect transistor including a pillar and a source/drain region within the pillar. The structure further comprises a capacitor including a first metal layer, a second metal layer, and a ferroelectric layer between the first metal layer and the second metal layer. The first metal layer adjoins the source/drain region.

In an embodiment, a method comprises forming a field-effect transistor including a source/drain region, and forming a capacitor including a first metal layer, a second metal layer, and a ferroelectric layer. The first metal layer includes a first vertically-extending section and a second vertically-extending section surrounding the first vertically-extending section. The second metal layer is arranged between the first vertically-extending section of the first metal layer and the second vertically-extending section of the first metal layer. The ferroelectric layer is arranged between the first metal layer and the second metal layer, and the second vertically-extending section of the first metal layer adjoins the source/drain region.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure at an initial fabrication stage of a processing method in accordance with embodiments of the invention.

FIG. 2 is a cross-sectional view of the structure at a fabrication stage of the processing method subsequent to FIG. 1.

FIG. 3 is a cross-sectional view of the structure at a fabrication stage of the processing method subsequent to FIG. 2.

FIG. 4 is a cross-sectional view of the structure at a fabrication stage of the processing method subsequent to FIG. 3.

FIG. 5 is a cross-sectional view of the structure at a fabrication stage of the processing method subsequent to FIG. 4.

FIG. 6 is a cross-sectional view of the structure at a fabrication stage of the processing method subsequent to FIG. 5.

FIG. 7 is a cross-sectional view of the structure at a fabrication stage of the processing method subsequent to FIG. 6.

FIG. 8 is a cross-sectional view of a structure at an initial fabrication stage of a processing method in accordance with alternative embodiments of the invention.

FIG. 9 is a cross-sectional view of the structure at a fabrication stage of the processing method subsequent to FIG. 8.

FIG. 10 is a cross-sectional view of the structure at a fabrication stage of the processing method subsequent to FIG. 9.

FIG. 11 is a cross-sectional view of the structure at a fabrication stage of the processing method subsequent to FIG. 10.

FIG. 12 is a cross-sectional view of the structure at a fabrication stage of the processing method subsequent to FIG. 11.

FIG. 13 is a cross-sectional view of a structure in accordance with alternative embodiments of the invention.

FIG. 14 is a top view of a structure in accordance with alternative embodiments of the invention.

FIG. 14A is a cross-sectional view taken generally along line 14A-14A in FIG. 14.

FIG. 15 is a cross-sectional view of the structure at a fabrication stage of the processing method subsequent to FIGS. 14, 14A.

FIG. 16 is a top view of a structure in accordance with alternative embodiments of the invention.

FIG. 16A is a cross-sectional view taken generally along line 16A-16A in FIG. 16.

FIG. 17 is a cross-sectional view of the structure at a fabrication stage of the processing method subsequent to FIGS. 16, 16A.

FIG. 18 is a top view of a structure in accordance with alternative embodiments of the invention.

FIG. 19 is a top view of a structure in accordance with alternative embodiments of the invention.

### DETAILED DESCRIPTION

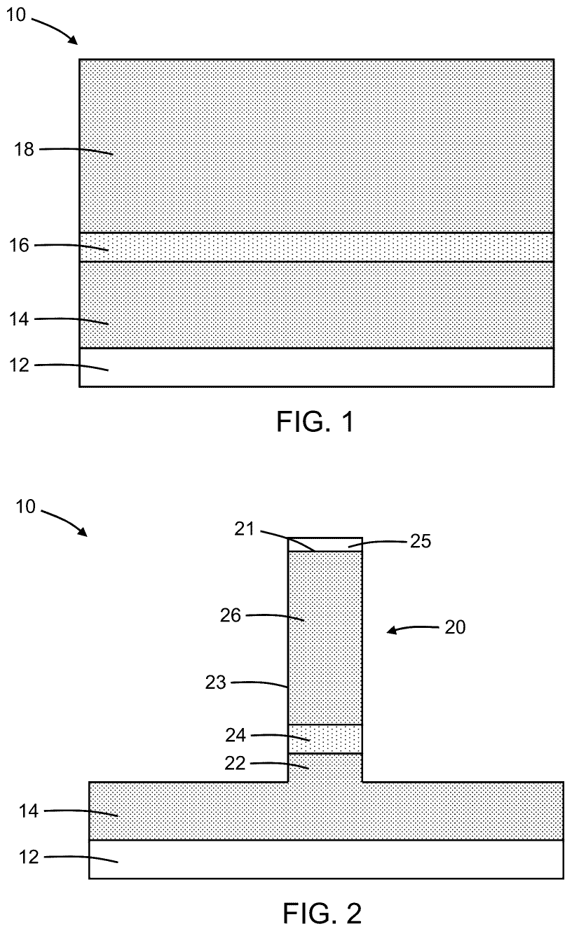

With reference to FIG. 1 and in accordance with embodiments of the invention, a structure 10 includes a semiconductor substrate 12, and a layer stack including a semiconductor layer 14, a semiconductor layer 16, and a semiconductor layer 18 arranged on the semiconductor substrate 12. The semiconductor layers 14, 16, 18 may be formed by an epitaxial growth process using the crystal structure of the semiconductor substrate 12 as a growth template. The semiconductor layer 14 may be formed by epitaxial growth situ doping adding an n-type dopant, such as phosphorous or arsenic. The semiconductor layer 16 may be formed by epitaxial growth without doping as intrinsic semiconductor material. The semiconductor layer 18 may be formed by epitaxial growth with doping adding an n-type dopant, such as phosphorous or arsenic.

With reference to FIG. 2 in which like reference numerals refer to like features in FIG. 1 and at a subsequent fabrication stage, the semiconductor layers 14, 16, 18 may be patterned by lithography and etching processes to form a pillar 20. A hardmask 25 used during patterning may remain on a top surface 21 of the pillar 20. The pillar 20 has a lower section 22 that includes doped semiconductor material from the semiconductor layer 14. The pillar 20 has a middle section 24 that includes intrinsic semiconductor material from the semiconductor layer 16. The pillar 20 has an upper section 26 that includes doped semiconductor material from the semiconductor layer 18. The middle section 24 is arranged in a vertical direction between the lower section 22 and the upper section 26. The pillar 20 projects upwardly away from the semiconductor substrate 12 and the lower section 22 is coupled to an underlying portion of the semiconductor layer 14 that is not patterned when the pillar 20 is formed. The pillar 20 has a sidewall 23 that extends fully about its outer perimeter. In an embodiment, the pillar 20 may be characterized by a cylindrical shape. In an embodiment, the pillar 20 may be a nanowire having a diameter of less than or equal to one nanometer.

In an embodiment, the lower section 22 and upper section 26 of the pillar 20 may represent source/drain regions of a field-effect transistor. As used herein, the term “source/drain region” means a region of semiconductor material that can function as either a source or a drain of a field-effect transistor. In an embodiment, the lower section 22 of the pillar 20 may represent a source of a field-effect transistor and the upper section 26 of the pillar 20 may represent a drain of the field-effect transistor. The middle section 24 of the pillar 20 may represent a channel region of the field-effect transistor that is arranged over the height of the pillar 20 between the source/drain region represented by the lower section 22 and the source/drain region represented by the upper section 26.

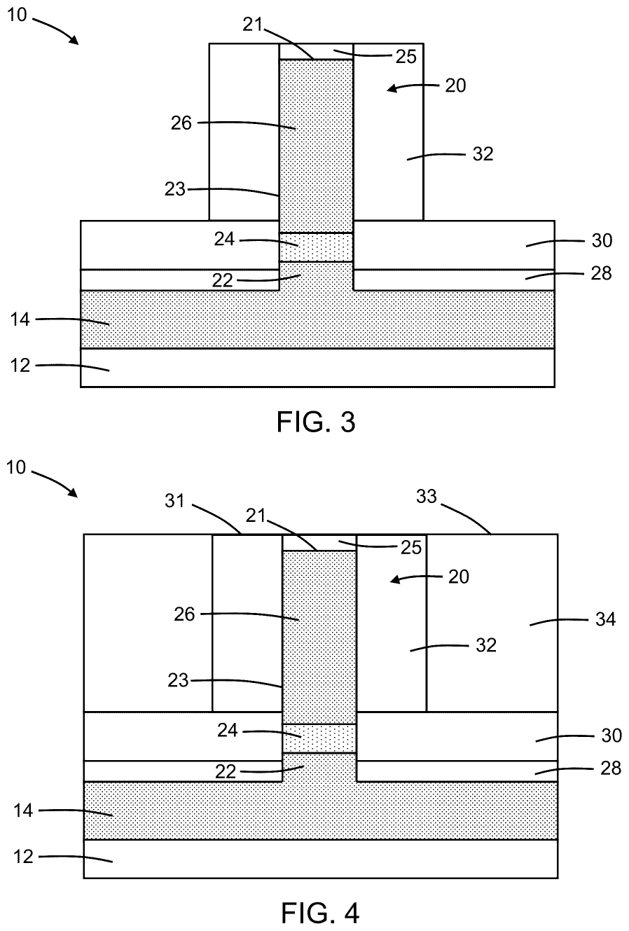

With reference to FIG. 3 in which like reference numerals refer to like features in FIG. 2 and at a subsequent fabrication stage, a dielectric layer 28 may be formed on the portion of the semiconductor layer 14 to which the lower section 22 of the pillar 20 is coupled. The dielectric layer 28 may be comprised of a dielectric material, such as silicon nitride, that is an electrical insulator. A layer 30 comprised of a sacrificial material, such as amorphous silicon, may be formed on the dielectric layer 28.

A spacer 32 comprised of a material, such as silicon dioxide, may be formed on a portion of the layer 30. The spacer 32, which may contact the sidewall 23 of the pillar 20, may fully surround the pillar 20 and may overlie a contacted portion of the layer 30. The spacer 32 may be formed by depositing a conformal layer of its constituent material and performing an anisotropic etching process. In an embodiment, the spacer 32 may be characterized by an annular shape centered about the pillar 20 and may therefore extend about the full outer perimeter of the pillar 20. The layer 30 establishes the location of the spacer 32 relative to the lower section 22, middle section 24, and upper section 26 of the pillar 20.

With reference to FIG. 4 in which like reference numerals refer to like features in FIG. 3 and at a subsequent fabrication stage, a layer 34 comprised of a sacrificial material, such as amorphous silicon, may be formed on the layer 30 and spacer 32. The layer 34 may be deposited and then planarized to have a top surface 33 that is substantially coplanar with the top surface 21 of the pillar 20. The spacer 32 is embedded inside the layer 34 with the spacer 32 having a top surface 31 that is substantially coplanar with the top surface 21 of the pillar 20 and that is coplanar with the top surface 33 of the layer 34.

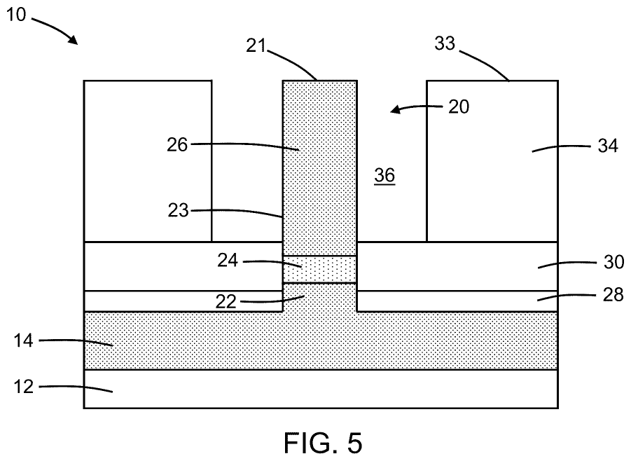

With reference to FIG. 5 in which like reference numerals refer to like features in FIG. 4 and at a subsequent fabrication stage, the spacer 32 may be removed selective to the pillar 20 and the layer 34 to form a trench 36. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. The trench 36 may fully surround a portion of the upper section 26 of the pillar 20 adjacent to the top surface 21 such that the sidewall 23 is exposed from the top surface 21 downward over the portion of the upper section 26. In an embodiment, the trench 36 may be characterized by an annular shape centered about the pillar 20 and may therefore extend about the full outer perimeter of the pillar 20. The trench 36 is arranged fully above the middle section 24 of the pillar 20.

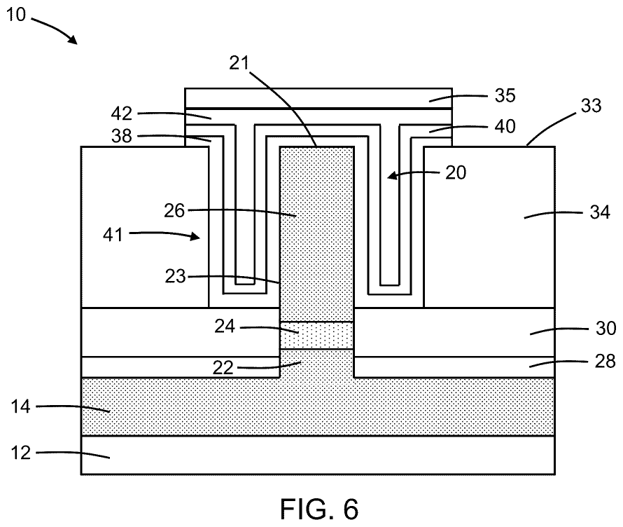

With reference to FIG. 6 in which like reference numerals refer to like features in FIG. 5 and at a subsequent fabrication stage, a metal layer 38, a ferroelectric layer 40, and a metal layer 42 are serially formed inside the trench 36. The metal layer 38 is positioned between the ferroelectric layer 40 and the upper section 26 of the pillar 20. In an embodiment, the metal layer 38 may adjoin and directly contact the sidewall 23 of the pillar 20 over the portion of the upper section 26 of the pillar 20 exposed by the trench 36. The ferroelectric layer 40 is positioned between the metal layer 38 and the metal layer 42. The metal layer 38, the ferroelectric layer 40, and the metal layer 42 may be patterned by lithography and etching processes to remove extraneous material from the top surface 33 of the layer 34. A hardmask 35 used during patterning may remain on an upper surface of the metal layer 42. Portions of the metal layer 38, the ferroelectric layer 40, and the metal layer 42 overlie the top surface 21 of the pillar 20 and the top surface 33 of the layer 34.

The metal layer 38 may be comprised of a metal, such as tantalum, tantalum nitride, titanium, titanium nitride, tungsten, aluminum, copper, or gold. The metal layer 42 may be comprised of a metal, such as tantalum, tantalum nitride, titanium, titanium nitride, tungsten, aluminum, copper, or gold. In an embodiment, the metal constituting the metal layer 38 may differ from the metal constituting the metal layer 42.

The ferroelectric layer 40 may be comprised of a ferroelectric material that is an electrical insulator. The ferroelectric material constituting the ferroelectric layer 40 may be deposited by, for example, atomic layer deposition and crystallized by an anneal following deposition. In an embodiment, the ferroelectric material may be comprised of a hafnium-based material. In an embodiment, the ferroelectric material may be comprised of hafnium oxide. In an embodiment, the ferroelectric material may be comprised of an oxide that contains hafnium and zirconium. In an embodiment, the ferroelectric material may be comprised of hafnium zirconium oxide. The ferroelectric material constituting the ferroelectric layer 40 is characterized by a pair of remanent polarization states that can be reversibly varied in response to an applied voltage and that are persistent and non-volatile after the electric field associated with the applied voltage is removed. The remnant polarization states may correspond to bits of binary data that are retained as stored content by the ferroelectric material of the ferroelectric layer 40 when the electric field is absent.

The metal layer 38 may represent an electrode of a metal-insulator-metal capacitor 41, the metal layer 42 may represent an electrode of the metal-insulator-metal capacitor 41, and the ferroelectric layer 40 may represent an insulator of the metal-insulator-metal capacitor 41. The height of the spacer 32 and, therefore, the depth of the trench 36 may be a parameter that is selected to determine the capacitance of the metal-insulator-metal capacitor 41. The metal layer 38 includes a portion that adjoins, and is in direct contact with, the upper section 26 of the pillar 20 at the sidewall 23. The entirety of the lower section 22 and the entirety of the middle section 24 of the pillar 20 are arranged in a vertical direction between the metal-insulator-metal capacitor 41 and the semiconductor substrate 12. The middle section 24 of the pillar 20 is arranged in a vertical direction fully between the metal-insulator-metal capacitor 41 and the lower section 22 of the pillar 20.

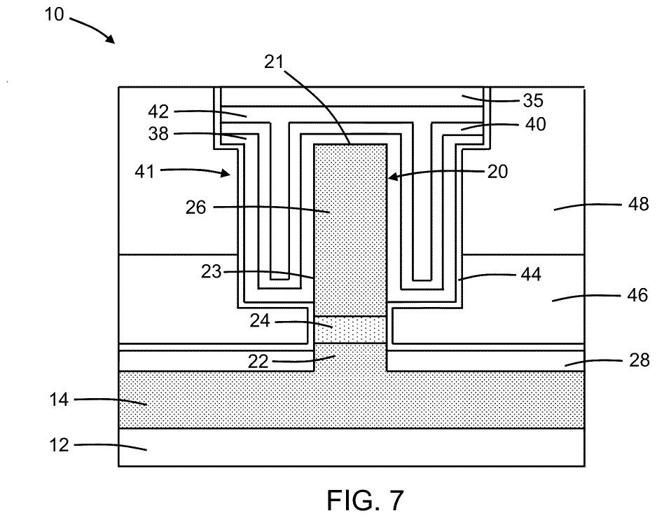

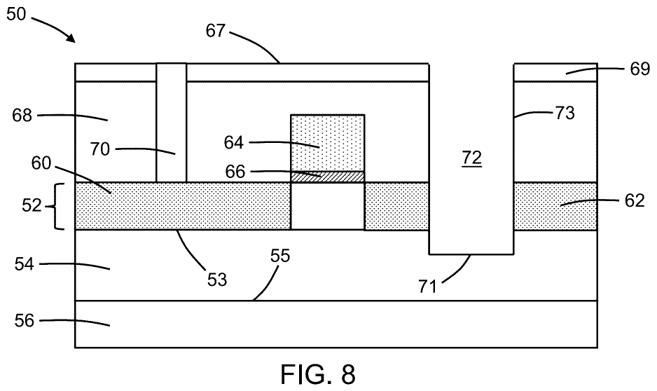

With reference to FIG. 7 in which like reference numerals refer to like features in FIG. 6 and at a subsequent fabrication stage, the layer 30 and the layer 34 may be removed. A gate dielectric layer 44 may be formed that coats the metal layer 42 and the portion of the pillar 20 not covered by the capacitor. The gate dielectric layer 44 may include a thin inner layer comprised of an oxide of silicon (e.g., silicon dioxide) and an outer layer comprised of a high-k dielectric material, such as hafnium oxide.

A gate electrode 46 may be formed in a lower portion of the space opened by the removal of the layer 30 and the layer 34, and a dielectric layer 48 may be formed in an upper portion of the space opened by the removal of the layer 30 and the layer 34. The gate electrode 46 may be a metal gate comprised of a work function metal (e.g., titanium nitride) and tungsten. The dielectric layer 48 may be comprised of a silicon oxide, such as silicon dioxide. A portion of the gate electrode 46 extends into an indent beneath the metal-insulator-metal capacitor 41 and surrounds the middle section 24 of the pillar 20 with the gate dielectric layer 44 providing electrical isolation.

A contact (not shown) may be formed that is coupled to the gate electrode 46, a contact (not shown) may be formed that is coupled by the semiconductor layer 14 to the lower section 22 of the pillar 20, and a contact (not shown) may be formed that is coupled to the metal layer 42 over the pillar 20. The contacts may be used to apply control voltages to the field-effect transistor for writing, erasing, and reading the metal-insulator-metal capacitor 41.

The field-effect transistor including the pillar 20 and the gate electrode 46 and the metal-insulator-metal capacitor 41 including the metal layer 38, the ferroelectric layer 40, and the metal layer 42 may be represent a one transistor-one capacitor bitcell of a ferroelectric random-access memory device. Multiple such bitcells may be formed in an array to construct the ferroelectric random-access memory device. The formation of the metal layer 38, the ferroelectric layer 40, and the metal layer 42 of the metal-insulator-metal capacitor 41 inside a trench 36 adjacent to the upper section 26 of the pillar 20 may improve the properties of the bitcell, such as an improvement of the polarization density in comparison with the bitcells of a conventional ferroelectric random-access memory device. The improvement of the polarization density may enable an improved memory window.

With reference to FIG. 8 and in accordance with alternative embodiments of the invention, a structure 50 includes a semiconductor layer 52, a dielectric layer 54, and a semiconductor substrate 56. In an embodiment, the semiconductor layer 52 may be comprised of a semiconductor material, such as single-crystal silicon. In an embodiment, the dielectric layer 54 may be comprised of a dielectric material, such as silicon dioxide, and the semiconductor substrate 56 may be comprised of a semiconductor material, such as single-crystal silicon. The dielectric layer 54 may have an interface 53 representing a boundary with the semiconductor layer 52 and an interface 55 representing a boundary with the semiconductor substrate 56. In an embodiment, the dielectric layer 54 may be a buried oxide layer of a silicon-on-insulator substrate, and the dielectric layer 54 may fully separate the semiconductor layer 52 from the semiconductor substrate 56.

A field-effect transistor may include a source/drain region 60 in the semiconductor layer 52, a source/drain region 62 in the semiconductor layer 52, a gate electrode 64 laterally between the source/drain region 60 and the source/drain region 62, and a gate dielectric layer 66 between the gate electrode 64 and the semiconductor layer 52. A channel region is arranged in the semiconductor layer 52 laterally between the source/drain region 60 and the source/drain region 62.

In an embodiment, the source/drain regions 60, 62 may contain a concentration of an n-type dopant, such as phosphorus, to provide n-type conductivity. The source/drain regions 60, 62 may be formed by implanting ions, such as ions including the n-type dopant, using an implantation mask. The implantation conditions, such as ion species, dose, and kinetic energy, may be selected to tune the electrical and physical characteristics of the source/drain regions 60, 62. In an alternative embodiment, the source/drain regions 60, 62 may contain a concentration of a p-type dopant, such as boron, to provide p-type conductivity. In an embodiment, the gate electrode 64 may be comprised of a conductor, such as doped polycrystalline silicon, and the gate dielectric layer 66 may be comprised of a dielectric material, such as silicon oxide (e.g., silicon dioxide).

A dielectric layer 68 and a dielectric layer 69 may be formed that overlie the field-effect transistor. In an embodiment, the dielectric layer 68 may be comprised of a dielectric material that is an electrical insulator. In an embodiment, the dielectric layer 68 may be comprised of a dielectric material, such as silicon oxide (e.g., silicon dioxide), that is an electrical insulator. In an embodiment, the dielectric layer 69 may be comprised of a dielectric material, such as silicon nitride, that is an electrical insulator. The dielectric layer 69 has a top surface 67, which may be flat in a horizontal plane. A contact 70 may be formed that extends through the dielectric layers 68, 69 and is coupled to the source/drain region 60. The contact 70 may be comprised of a metal, such as tungsten.

A trench 72 is formed by lithography and etching processes that extends fully through the dielectric layers 68, 69 and the source/drain region 62, as well as extending partially through the dielectric layer 54. The trench 72 has a trench bottom 71 that is located in a vertical direction inside the dielectric layer 54 below the interface 53 and above the interface 55. The trench 72 also has a sidewall 73 that extends in a vertical direction from the top surface 67 to the trench bottom 71. A lower portion of the trench 72, which is between the interface 53 and the interface 55, may be surrounded by the dielectric layer 54. A middle portion of the trench 72 extends through the source/drain region 62 and, in an embodiment, the middle portion of the trench 72 may be fully surrounded by the source/drain region 62. In an embodiment, an upper portion of the trench 72 may be fully surrounded by the dielectric layers 68, 69.

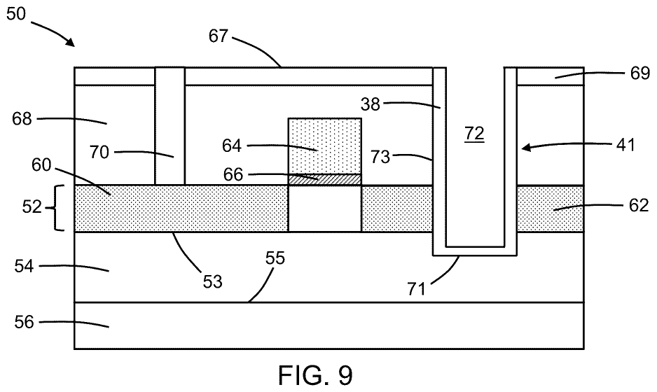

With reference to FIG. 9 in which like reference numerals refer to like features in FIG. 8 and at a subsequent fabrication stage, the metal layer 38 of the metal-insulator-metal capacitor 41 may be formed with a conformal thickness on the sidewall 73 as a liner inside of the trench 72. The metal layer 38 partially fills the trench 72. The metal layer 38 includes a horizontally-extending section that adjoins the trench bottom 71 and a vertically-extending section that adjoins the sidewall 73 and that is connected to the horizontally-extending section. The vertically-extending section of the metal layer 38 includes a portion that adjoins, and is in direct contact with, a portion of the source/drain region 62 and that is fully surrounded by the source/drain region 62. The vertically-extending section of the metal layer 38 includes a portion arranged in a lower portion of the trench 72 inside the dielectric layer 54 and below the interface 53. In an embodiment, the portion of the vertically-extending section of the metal layer 38 in the lower portion of the trench 72 may be fully surrounded by the dielectric layer 54.

In an embodiment, the vertically-extending section of the metal layer 38 may be circular in cross section when viewed from a vertical perspective. In an embodiment, the vertically-extending section of the metal layer 38 may be rectangular in cross section when viewed from a vertical perspective.

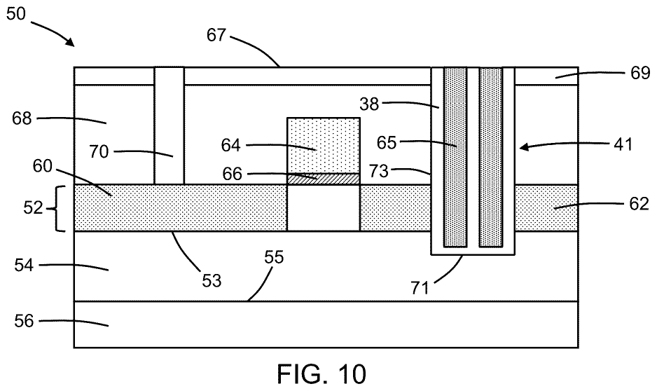

With reference to FIG. 10 in which like reference numerals refer to like features in FIG. 9 and at a subsequent fabrication stage, a layer 65 may be deposited inside of the trench 72 and patterned by lithography and etching processes. The patterned layer 65 extends from the trench bottom 71 to the top surface 67 of the dielectric layer 69, and the patterned layer 65 adjoins the metal layer 38 formed on the trench bottom 71 and the sidewall 73 of the trench 72. A portion of the trench 72 is opened after the layer 65, which may be comprised of silicon dioxide, is patterned. In an embodiment, the patterned layer 65 may have the shape of a hollow right circular cylinder with an inner boundary surrounding open space and an outer boundary that contacts the vertically-extending section of the metal layer 38.

A portion of the horizontally-extending section of the metal layer 38 at the trench bottom 71 is exposed inside of the inner boundary of the patterned layer 65. A vertically-extending section of the metal layer 38 of the metal-insulator-metal capacitor 41 is formed on the portion of the horizontally-extending section of the metal layer 38 at the trench bottom 71 and is surrounded by the patterned layer 65. The vertically-extending section of the metal layer 38 that adjoins the horizontally-extending section of the metal layer 38 at the trench bottom 71 is surrounded by, and is spaced inwardly from, the vertically-extending section of the metal layer 38 that adjoins the sidewall 73 of the trench 72.

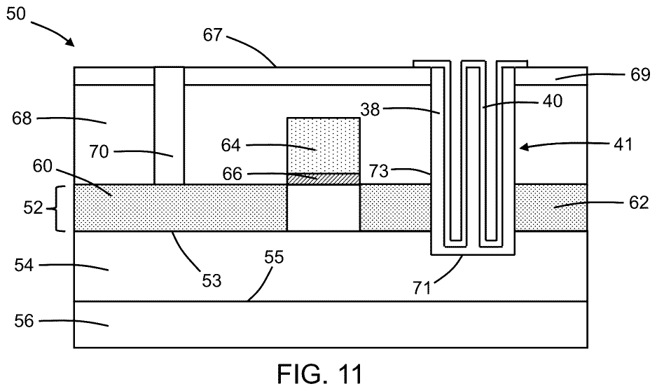

With reference to FIG. 11 in which like reference numerals refer to like features in FIG. 10 and at a subsequent fabrication stage, the layer 65 is removed by a selective etching process to open a portion of the trench 72 that is arranged between the vertically-extending sections of the metal layer 38. In an embodiment, the opened portion of the trench 72 may have the shape of a hollow right circular cylinder when viewed from a vertical perspective.

The ferroelectric layer 40 of the metal-insulator-metal capacitor 41 is formed inside the portion of the trench 72 opened by the removal of the layer 65. The ferroelectric layer 40 may be formed with a conformal thickness on the vertically-extending sections and the horizontally-extending section of the metal layer 38 inside of the trench 72.

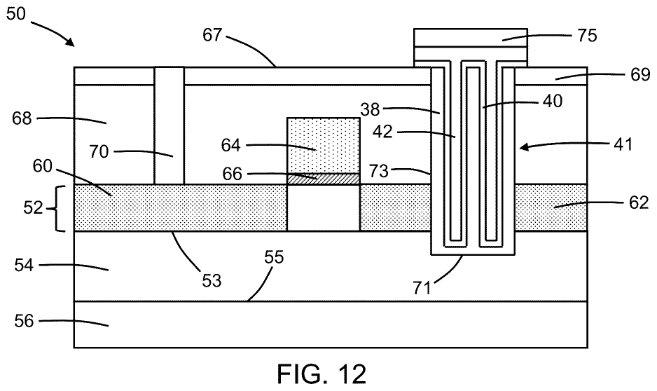

With reference to FIG. 12 in which like reference numerals refer to like features in FIG. 11 and at a subsequent fabrication stage, the metal layer 42 of the metal-insulator-metal capacitor 41 may be formed inside the portion of the trench 72 opened by the removal of the layer 65. The metal layer 42 is represented a vertically-extending section, and the ferroelectric layer 40 is positioned as an electrically-insulating separator between the metal layer 38 and the metal layer 42. In an embodiment, the vertically-extending section of the metal layer 42 may be annular in cross section when viewed from a vertical perspective. In an embodiment, the vertically-extending section of the metal layer 42 may be a rectangular annulus in cross section when viewed from a vertical perspective.

The metal layer 38 and the ferroelectric layer 40 may be patterned by lithography and etching processes to remove excess material and clear the top surface 67 of the dielectric layer 69 surrounding the metal-insulator-metal capacitor 41. A hardmask 75 used during patterning may remain on the top surface 67 of the dielectric layer 69.

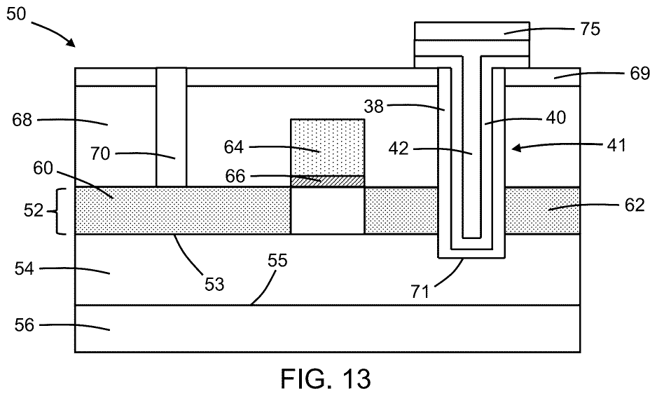

With reference to FIG. 13 and in accordance with embodiments of the invention, the metal-insulator-metal capacitor 41 may be formed without the central vertically-extending section of the metal layer 38. The vertically-extending section of the metal layer 42 is centrally-arranged as a cylindrical core inside the trench 72 and has an outer perimeter that is surrounded by both the metal layer 38 and the ferroelectric layer 40.

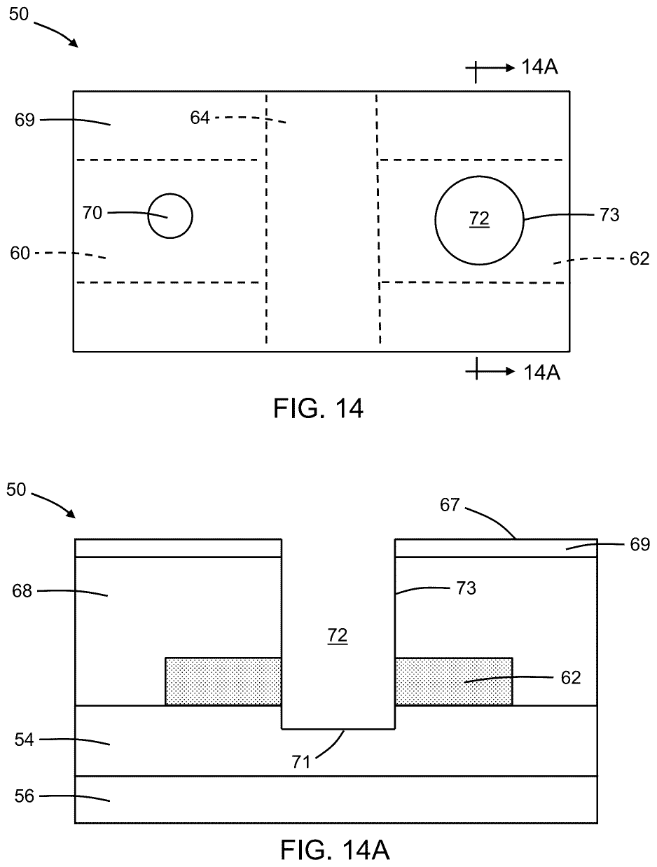

With reference to FIGS. 14, 14A and in accordance with embodiments of the invention, the trench 72 in which the metal-insulator-metal capacitor 41 is formed may be round in shape at the sidewall 73. The trench 72 may include a middle portion that extends through the source/drain region 62 and a lower portion arranged inside the dielectric layer 54.

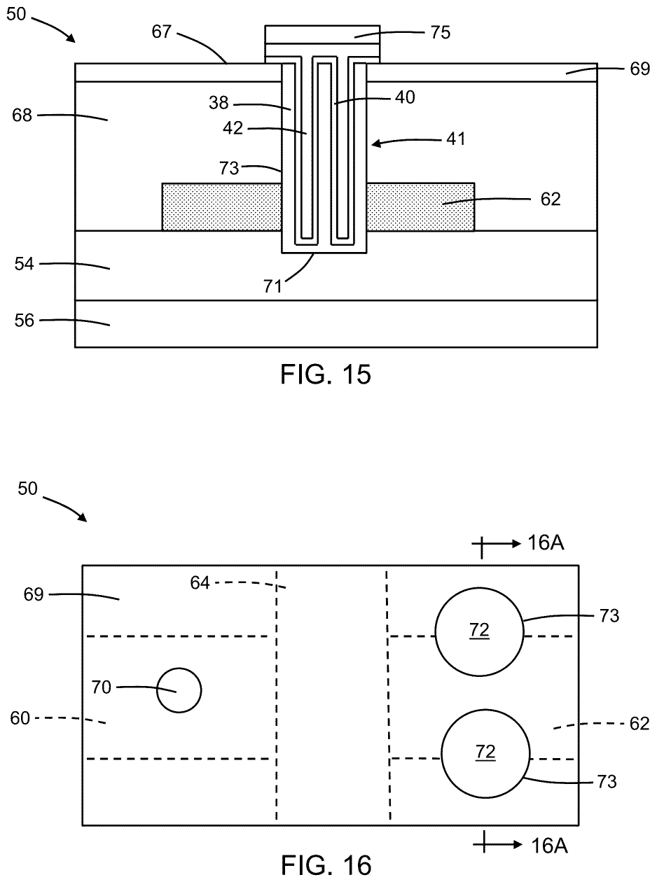

With reference to FIG. 15 in which like reference numerals refer to like features in FIGS. 14, 14A and at a subsequent fabrication stage, the metal-insulator-metal capacitor 41 may be formed inside the trench 72 and may conform to the round shape of the trench 72. The metal-insulator-metal capacitor 41 includes the metal layer 38, the ferroelectric layer 40, and the metal layer 42 that are formed inside the trench 72. A portion of the metal layer 38 adjoins, and is surrounded by, the source/drain region 62 at the sidewall 73 of the trench 72.

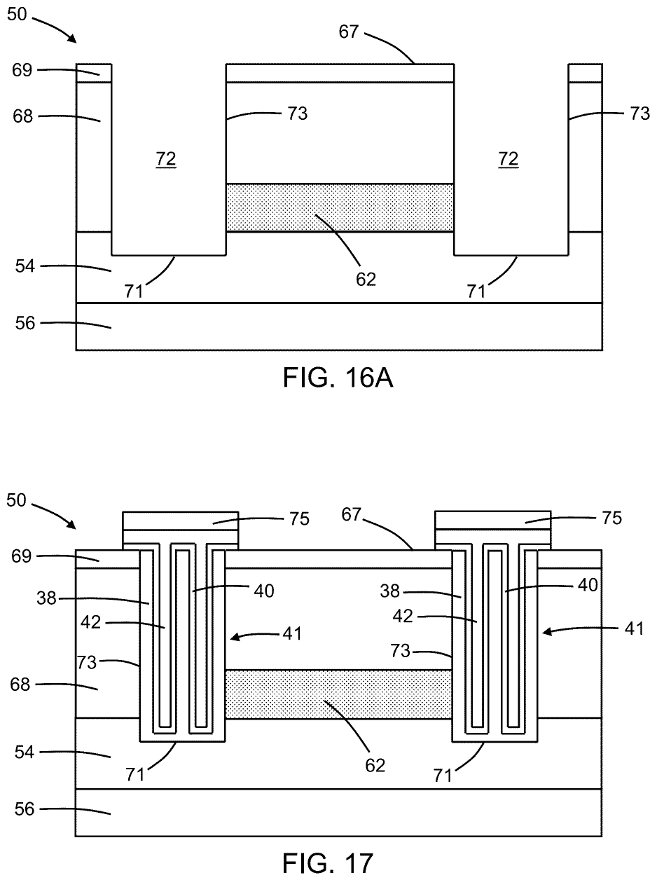

With reference to FIGS. 16, 16A and in accordance with embodiments of the invention, the trench 72 may be duplicated and the duplicates of the trench 72 may be laterally offset from each other such that only a portion of each trench 72 is surrounded by the source/drain region 62. Each trench 72 may include a middle portion that extends through the source/drain region 62 and a lower portion arranged inside the dielectric layer 54.

With reference to FIG. 17 in which like reference numerals refer to like features in FIGS. 16, 16A and at a subsequent fabrication stage, instances of the metal-insulator-metal capacitor 41 may be formed in the trenches 72 and may conform to the round shapes of the trenches 72. Each instance of the metal-insulator-metal capacitor 41 includes the metal layer 38, the ferroelectric layer 40, and the metal layer 42. A portion of the metal layer 42 of each instance of the metal-insulator-metal capacitor 41 adjoins, and is in direct contact with, a different portion of the source/drain region 62. The transistor and the instances of the metal-insulator-metal capacitor 41 may represent a one transistor-two capacitor bitcell of a ferroelectric random-access memory device.

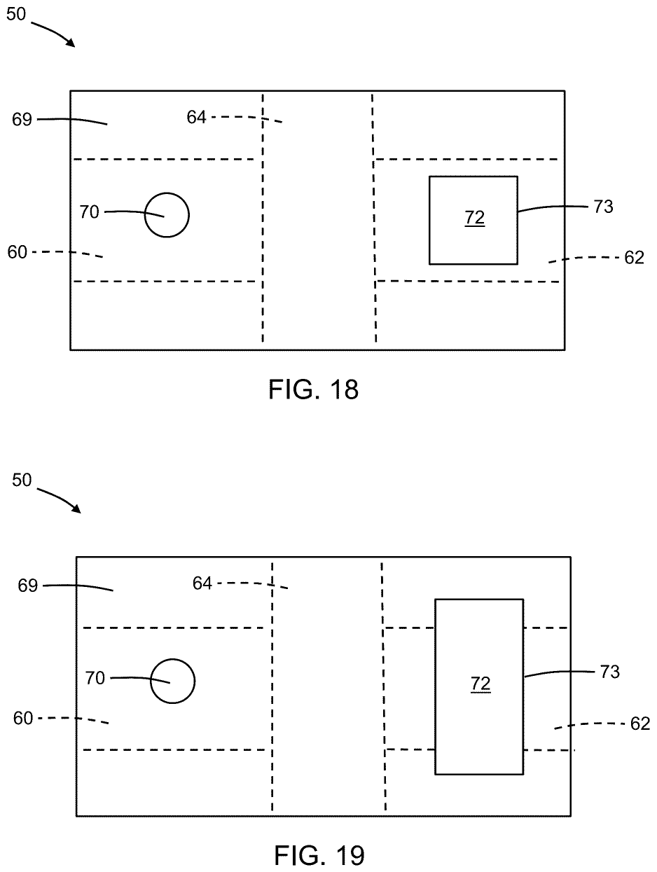

With reference to FIG. 18 and in accordance with embodiments of the invention, the trench 72 in which the metal-insulator-metal capacitor 41 is formed may be rectangular in shape and may include a middle portion that extends through the source/drain region 62. The metal layer 38, the ferroelectric layer 40, and the metal layer 42, which are subsequently formed, conform to the rectangular shape of the trench 72. A portion of the subsequently-formed metal layer 38 adjoins, and is surrounded by, the source/drain region 62 at the sidewall 73 of the rectangular trench 72.

With reference to FIG. 19 and in accordance with embodiments of the invention, the trench 72 in which the metal-insulator-metal capacitor 41 is formed may be rectangular in shape and may include a middle portion that extends through the source/drain region 62. The source/drain region 62 includes a portion positioned on one side of the trench 72 and a portion positioned between the trench 72 and the gate electrode 64, and the trench 72 adjoins each of these disconnected portions of the source/drain region 62. The metal layer 38, the ferroelectric layer 40, and the metal layer 42, which are subsequently formed, conform to the rectangular shape of the trench 72. A portion of the subsequently-formed metal layer 38 adjoins the source/drain region 62 at the sidewall 73 of the rectangular trench 72.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. A feature may “overlie” another feature if a feature is positioned over another feature. Different features may “overlap” if a feature extends over, and covers a part of, another feature. A feature may “underlie” another feature if a feature is positioned beneath another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a field-effect transistor including a first source/drain region; and
a first capacitor including a first metal layer, a second metal layer, and a ferroelectric layer, the first metal layer including a first vertically-extending section and a second vertically-extending section surrounding the first vertically-extending section, the second metal layer between the first vertically-extending section of the first metal layer and the second vertically-extending section of the first metal layer, the ferroelectric layer between the first metal layer and the second metal layer, and the second vertically-extending section of the first metal layer adjoining the first source/drain region.

2. The structure of claim 1 wherein the first metal layer comprises a first metal, and the second metal layer comprises a second metal different from the first metal.

3. The structure of claim 2 wherein the ferroelectric layer comprises a ferroelectric material that is an electrical insulator, and the ferroelectric material separates the first metal of the first metal layer from the second metal of the second metal layer.

4. The structure of claim 1 further comprising:
a first trench including a first portion adjoining the first source/drain region,
wherein the second vertically-extending section of the first metal layer adjoins the first source/drain region inside the first portion of the first trench.

5. The structure of claim 4 further comprising:
a semiconductor layer;
a semiconductor substrate; and
a dielectric layer between the semiconductor layer and the semiconductor substrate, the dielectric layer having an interface with the semiconductor layer,
wherein the first source/drain region is positioned in the semiconductor layer, the first trench includes a second portion in the dielectric layer, and the first vertically-extending section of the first metal layer extends into the second portion of the first trench.

6. The structure of claim 5 wherein the first trench includes a trench bottom inside the dielectric layer, the first metal layer includes a horizontally-extending section between the interface and the trench bottom, and the horizontally-extending section is connected to the first vertically-extending section and the second vertically-extending section.

7. The structure of claim 6 wherein the first trench includes a sidewall, and the second vertically-extending section of the first metal layer adjoins the first source/drain region along the sidewall of the trench.

8. The structure of claim 5 wherein the first source/drain region is a drain of the field-effect transistor, and the field-effect transistor further includes a source in the semiconductor layer and a gate electrode that overlies the semiconductor layer laterally between the source and the drain.

9. The structure of claim 4 wherein the first portion of the first trench is fully surrounded by the first source/drain region.

10. The structure of claim 4 wherein the first portion of the first trench is partially surrounded by the first source/drain region.

11. The structure of claim 4 further comprising:
a second trench including a portion adjoining the first source/drain region; and
a second capacitor inside the second trench, the second capacitor including a metal layer coupled to the first source/drain region.

12. A structure comprising:
a field-effect transistor including a pillar and a first source/drain region within the pillar; and
a capacitor including a first metal layer, a second metal layer, and a ferroelectric layer between the first metal layer and the second metal layer, the first metal layer adjoining the first source/drain region.

13. The structure of claim 12 wherein the first metal layer comprises a first metal, and the second metal layer comprises a second metal different from the first metal.

14. The structure of claim 13 wherein the ferroelectric layer comprises a ferroelectric material that is an electrical insulator, and the ferroelectric material separates the first metal of the first metal layer from the second metal of the second metal layer.

15. The structure of claim 12 wherein the pillar includes a second source/drain region and a channel region between the first source/drain region and the second source/drain region, and further comprising:
a semiconductor substrate,
wherein the channel region is vertically arranged between the capacitor and the semiconductor substrate.

16. The structure of claim 12 wherein the pillar includes a second source/drain region and a channel region between the first source/drain region and the second source/drain region, and further comprising:
a semiconductor substrate,
wherein the channel region is vertically arranged between the capacitor and the second source/drain region.

17. The structure of claim 12 wherein the capacitor fully surrounds the first source/drain region.

18. The structure of claim 12 wherein the pillar is a nanowire.

19. The structure of claim 12 wherein the pillar has a sidewall, and the first metal layer adjoins the sidewall of the pillar.

20. A method comprising:
forming a field-effect transistor including a source/drain region; and
forming a capacitor including a first metal layer, a second metal layer, and a ferroelectric layer,
wherein the first metal layer includes a first vertically-extending section and a second vertically-extending section surrounding the first vertically-extending section, the second metal layer is arranged between the first vertically-extending section of the first metal layer and the second vertically-extending section of the first metal layer, the ferroelectric layer is arranged between the first metal layer and the second metal layer, and the second vertically-extending section of the first metal layer adjoins the source/drain region.
